(19) United States
(12) Patent Application Publication
(10) Pub. No.: US 2016/0111529 A1
(43) Pub. Date: Apr. 21, 2016

(54) SEMICONDUCTOR DEVICE

(71) Applicant: Toyota Jidosha Kabushiki Kaisha, Toyota-shi (JP)

(72) Inventors: Yasuhiro Hirabayashi, Toyota-shi (JP); Masaru Senoo, Okazaki-shi (JP)

(21) Appl. No.: 14/885,148

(22) Filed: Oct. 16, 2015

(30) Foreign Application Priority Data
Oct. 17, 2014 (JP) 2014-212830

(51) Int. Cl. H01L 29/739; H01L 29/10

(52) U.S. Cl. CPC H01L 29/7397; H01L 29/1095

(57) ABSTRACT

A semiconductor device includes a semiconductor substrate. Dummy trenches and a grid-structured gate trench located between the dummy trenches are provided in the front surface. An emitter region, a first anode region, a first barrier region, and a first pillar region are provided in a cell region surrounded by the grid-structured gate trench. A drift region, a collector region, and a cathode region are provided in the semiconductor substrate. The first barrier region is an n-type region being in contact with a gate insulating film at a position on the rear surface side of the first anode region. The first pillar region is an n-type region extending along a thickness direction, being in contact with a front surface electrode, connected to the first barrier region, and separated from the gate insulating film.

### CROSS-REFERENCE TO RELATED APPLICATION

This application claims priority to Japanese Patent Application No. 2014-212830 filed on Oct. 17, 2014, the contents of which are hereby incorporated by reference into the present application.

### TECHNICAL FIELD

This specification discloses a technique relating to a semiconductor device (reverse conducting-insulated gate bipolar transistor, RC-IGBT) having both the function of an IGBT and the function of a diode.

### DESCRIPTION OF RELATED ART

Japanese Patent Application Publication No. 2013-251468 (hereinafter referred to as Patent Literature 1) discloses an IGBT. This IGBT has a gate trench and a dummy trench. A gate electrode insulated from a semiconductor substrate is located in the gate trench. A dummy electrode insulated from the semiconductor substrate is located in the dummy trench. The potential of the dummy electrode is independent of the potential of the gate electrode. Providing the gate trench and the dummy trench in this way reduces a gate capacitance, thereby accelerating switching operation.

Japanese Patent Application Publication No. 2013-48230 (hereinafter referred to as Patent Literature 2) discloses an RC-IGBT. This RC-IGBT has an IGBT structure configured of an emitter region of an n-type, a body region of a p-type, a drift region of the n-type, a collector region of the n-type, a trench gate electrode, and others. The p-type body region also functions as an anode region to further provide a diode structure. In this RC-IGBT, a barrier region of the n-type is located under the body region doubling as the anode region. A pillar region of the n-type is provided to connect the barrier region and a front surface electrode (doubling as an emitter electrode and an anode electrode). In this RC-IGBT, the barrier region is maintained at a potential close to the potential of the front surface electrode. This makes it difficult to turn on a diode configured by a pn junction between the body region and the barrier region. This diode is turned on if the potential of the front surface electrode becomes higher. The RC-IGBT of Patent Literature 2 uses the barrier region and the pillar region to suppress flow of holes from the p-type body region into the n-type barrier region and the n-type drift region, thereby suppressing a reverse recovery current in the diode.

### BRIEF SUMMARY

An RC-IGBT having a barrier region and a pillar region such as that of Patent Literature 2 can also reduce a gate capacitance and achieve switching operation at a higher speed through provision of a dummy trench as described in Patent Literature 1. In this case, the following RC-IGBT structure is preferable for reducing the ON voltage of the IGBT: a large number of gate trenches is located between two dummy trenches, and a pillar region is provided in a semiconductor region between the gate trenches. It is also preferable that a clearance between two dummy trenches be narrowed for reducing the gate capacitance sufficiently. This necessitates narrowing of each clearance between the gate trenches. However, narrowing each clearance between the gate trenches narrows a clearance between the pillar region and the gate trench. Narrowing the clearance between the pillar region and the gate trench makes a gate potential become influential in changing the operating characteristics of the pillar region. This leads to unstable operation of a pn diode (a pn junction between a body region and a barrier region). Thus, the aforementioned structure finds difficulty in achieving all of a low ON voltage, a low gate capacitance, and stable operation of the pn diode.

A semiconductor device disclosed herein comprises: a semiconductor substrate; a front surface electrode located on a front surface of the semiconductor substrate; and a rear surface electrode located on a rear surface of the semiconductor substrate. A plurality of dummy trenches and a grid-structured gate trench are provided in the front surface. The grid-structured gate trench is located between the dummy trenches. The grid-structured gate trench comprises: a plurality of first gate trenches extending along the dummy trenches on the front surface; and a plurality of second gate trenches connecting the first gate trenches to each other. A gate insulating film and a gate electrode are located in the grid-structured gate trench. The gate electrode is insulated from the semiconductor substrate by the gate insulating film. A dummy insulating film and a dummy electrode are located in the respective dummy trenches. Each dummy electrode is electrically separated from the gate electrode. Each dummy electrode is insulated from the semiconductor substrate by the dummy insulating film. The semiconductor substrate comprises an emitter region, a first anode region, a first barrier region, a first pillar region, a drift region, a collector region, and a cathode region. The emitter region is of an n-type, located in a cell region which is a region surrounded by the first gate trenches and the second gate trenches, and in contact with the gate insulating film and the front surface electrode. The first anode region is of a p-type, located in the cell region, in contact with the gate insulating film at a position on a rear surface side of the emitter region, and in contact with the front surface electrode. The first barrier region is of the n-type, located in the cell region, and in contact with the gate insulating film at a position on the rear surface side of the first anode region. The first pillar region is of the n-type, located in the cell region, configured to extend along a thickness direction of the semiconductor substrate, in contact with the front surface electrode, connected to the first barrier region, and separated from the gate insulating film. The drift region is of the n-type, located on the rear surface side of the first barrier region, separated from the first anode region by the first barrier region. The drift region has an n-type impurity concentration lower than that in the first barrier region. The collector region is of the p-type and in contact with the rear surface electrode. The cathode region is of the n-type, is in contact with the rear surface electrode, and has an n-type impurity concentration higher than that in the drift region.

In this semiconductor device, a pn junction between the first anode region and the first barrier region configures a pn diode. The first anode region also functions as a body region of an IGBT. That is, the IGBT is configured of the emitter region, the first anode region, the first barrier region, the drift region, the collector region, the gate electrode, and others. In this semiconductor device, a plurality of first gate trenches (the trenches extending along the dummy trenches) and the second gate trenches connecting the first gate trenches to each other are located between the dummy trenches. The first gate trenches and the second gate trenches configure the grid-structured gate trench. The emitter region, the first anode region, and the first barrier region (that is, a switching part of the IGBT) are located in the cell region surrounded by the first gate trenches and the second gate trenches. When the IGBT is ON, holes flow so as to bypass the trenches. This makes holes flowing so as to bypass the first gate trenches and holes flowing so as to bypass the second gate trenches flow into the drift region on a rear surface side of the cell region. This activates a conductivity modulation phenomenon to considerably reduce the resistance of this drift region. As a result, the ON voltage of the IGBT is reduced. The formation of the gate trench into a grid structure reduces the ON voltage. Thus, a low ON voltage can be achieved while a clearance between the gate trenches (that is, a clearance between the first gate trenches and a clearance between the second gate trenches) is not required to be narrowed. As a result, a broad clearance can be provided between the pillar region located in the cell region and the grid-structured gate trench. This can make influence of a gate potential less influential on the pillar region, thereby achieving stable operation of the pn diode. Furthermore, since the low ON voltage is achieved by the grid-structured gate trench as described above, the low ON voltage can be achieved without disposing a large number of gate trenches between the dummy trenches. A number of gate trenches to be located between the dummy trenches can be small, thereby narrowing a clearance between the dummy trenches. Narrowing the clearance between the dummy trenches can reduce a gate capacitance effectively, thereby increasing a switching speed of the IGBT.

### BRIEF DESCRIPTION OF DRAWINGS

FIG. 1 is a vertical sectional view of a semiconductor device 10 (sectional view taken along a line I-I of FIGS. 2 and 3);

FIG. 2 is a vertical sectional view of the semiconductor device 10 (sectional view taken along a line II-II of FIGS. 1 and 3);

FIG. 3 is a plan view showing a layout of a trench 14, a trench 15, and a pillar region 35 in a front surface 12a of the semiconductor device 10;

FIG. 4 is a perspective view of the semiconductor device 10 showing a cross section corresponding to that of FIG. 1 while showing the front surface 12a of a semiconductor substrate 12;

FIG. 5 is a plan view corresponding to FIG. 3 and showing the semiconductor device according to a first modification;

FIG. 6 is a plan view corresponding to FIG. 3 and showing the semiconductor device according to a second modification;

FIG. 7 is a plan view corresponding to FIG. 3 and showing the semiconductor device according to a third modification;

FIG. 8 is a plan view corresponding to FIG. 3 and showing the semiconductor device according to a fourth modification;

FIG. 9 is a plan view corresponding to FIG. 3 and showing the semiconductor device according to a fifth modification;

FIG. 10 is a plan view corresponding to FIG. 3 and showing the semiconductor device according to a sixth modification;

FIG. 11 is a plan view corresponding to FIG. 3 and showing the semiconductor device according to a seventh modification;

FIG. 12 is a plan view corresponding to FIG. 3 and showing the semiconductor device according to an eighth modification;

FIG. 13 is a plan view corresponding to FIG. 3 and showing the semiconductor device according to a ninth modification;

FIG. 14 is a plan view corresponding to FIG. 3 and showing the semiconductor device according to a tenth modification;

FIG. 15 is a plan view corresponding to FIG. 3 and showing the semiconductor device according to an eleventh modification;

FIG. 16 is a perspective view corresponding to FIG. 4 and showing the semiconductor device according to a twelfth modification; and

FIG. 17 is a perspective view corresponding to FIG. 4 and showing the semiconductor device according to a thirteenth modification.

### DETAILED DESCRIPTION

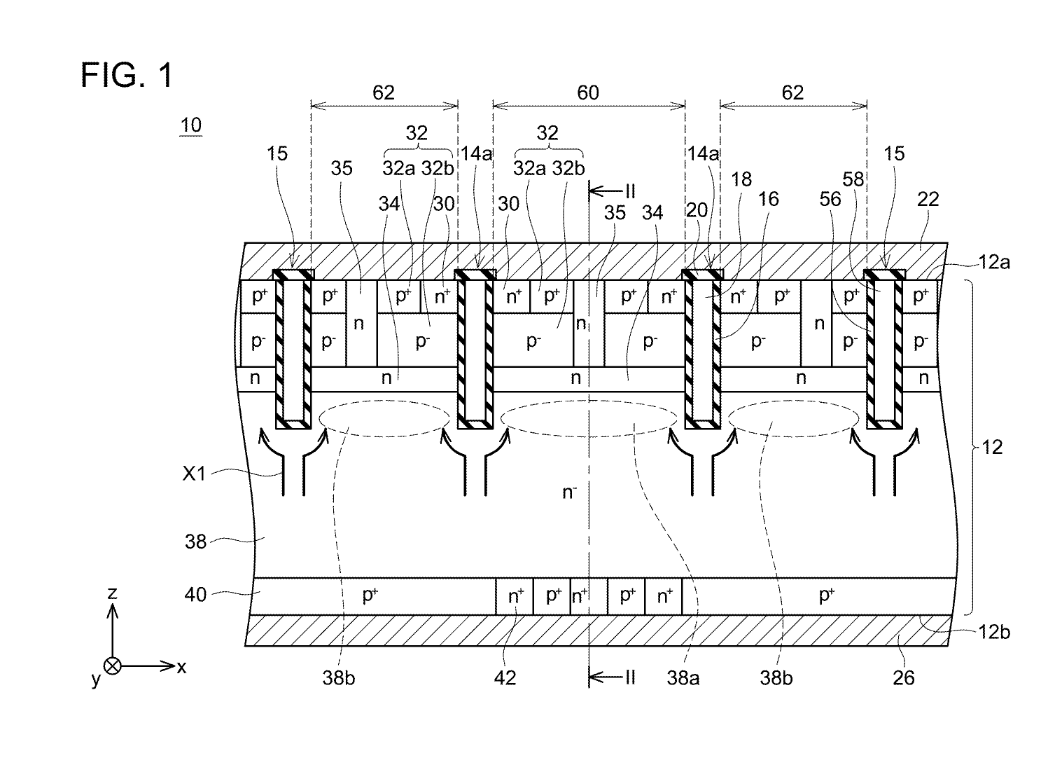

A semiconductor device 10 according to an embodiment shown in FIGS. 1 to 4 is an RC-IGBT including an IGBT and a diode. The semiconductor device 10 has a semiconductor substrate 12 made of Si. Referring to FIGS. 1 to 4, a direction z is a thickness direction of the semiconductor substrate 12, a direction x is a direction parallel to a front surface 12a of the semiconductor substrate 12, and a direction y is a direction perpendicular to the directions z and x. A front surface electrode 22 is located on the front surface 12a of the semiconductor substrate 12. A rear surface electrode 26 is located on a rear surface 12b of the semiconductor substrate 12.

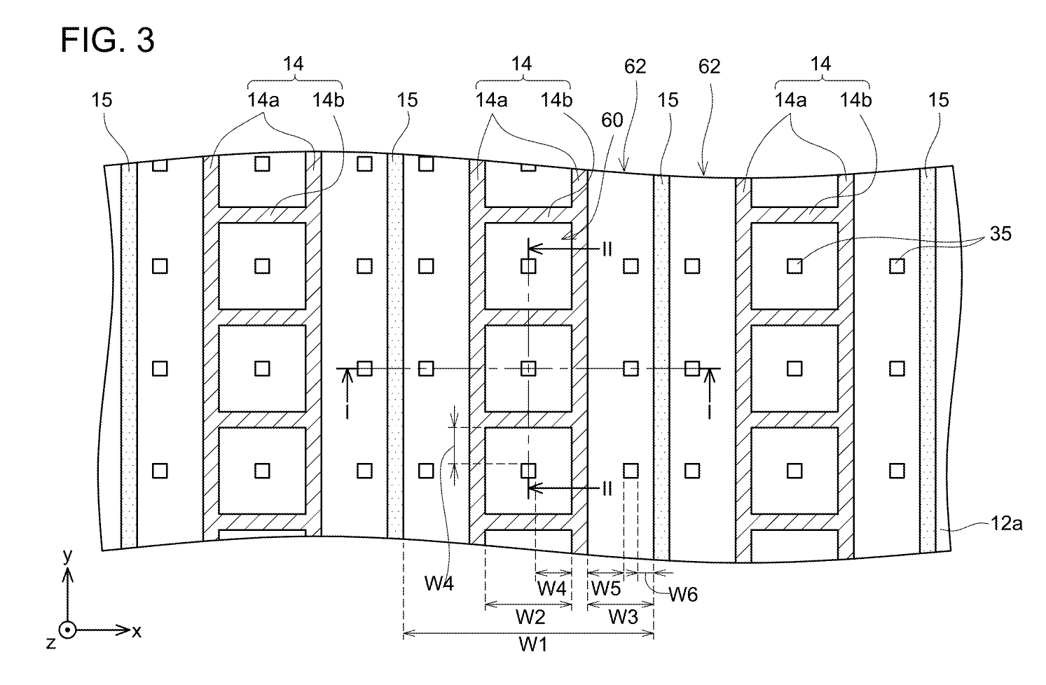

As shown in FIG. 3, a plurality of grid-structured gate trenches 14 and a plurality of dummy trenches 15 are provided in the front surface 12a of the semiconductor substrate 12. The grid-structured gate trenches 14 are hatched with diagonal lines and the dummy trenches 15 are hatched with dots in FIG. 3, so as to be easily seen. Each of the grid-structured gate trenches 14 has two first gate trenches 14a extending in straight lines along the direction y and a plurality of second gate trenches 14b extending in straight lines along the direction x. Two first gate trenches 14a configure one pair. The two first gate trenches 14a configuring one pair are spaced apart in the direction x and extend substantially parallel to each other. The second gate trenches 14b are provided between the two first gate trenches 14a configuring one pair. Each of the second gate trenches 14b connects the two first gate trenches 14a in a pair to each other. That is, one grid-structured gate trench 14 has a ladder shape in the front surface 12a. As shown in FIGS. 1, 2, and 4, the grid-structured gate trenches 14 extend along the direction z (extend downward) from the front surface 12a of the semiconductor substrate 12. In the description below, a semiconductor region in a range surrounded by the first gate trenches 14a and the second gate trenches 14b is called a cell region 60. In the description below, a semiconductor region located between the grid-structured gate trench 14 and the dummy trench 15 is called an external region 62.

As shown in FIG. 3, the dummy trenches 15 extend in straight lines along the direction y. That is, the dummy trenches 15 extend substantially parallel to the first gate trenches 14a. As shown in FIGS. 1, 2, and 4, the dummy trenches 15 extend in the direction z (extend downward) from the front surface 12a of the semiconductor substrate 12. In the front surface 12a of the semiconductor substrate 12, the grid-structured gate trenches 14 and the dummy trenches 15 are located alternately in the direction x. That is, one dummy trench 15 is located between two grid-structured gate trenches 14. One grid-structured gate trench 14 is located between two dummy trenches 15.

As shown in FIG. 1, each grid-structured gate trench 14 has an inner surface covered with a gate insulating film 16. A gate electrode 18 is located in each grid-structured gate trench 14. The gate electrodes 18 are insulated from the semiconductor substrate 12 by the gate insulating films 16. Each gate electrode 18 has an upper surface covered with an interlayer insulating film 20. The gate electrodes 18 are insulated from the front surface electrode 22 by the interlayer insulating films 20. Each gate electrode 18 is connected to a gate pad through a gate wiring at a position not shown in the drawings. The potential of the gate electrodes 18 is controlled through the gate pad.

As shown in FIG. 1, each dummy trench 15 has an inner surface covered with a dummy insulating film 56. A dummy electrode 58 is located in each dummy trench 15. In the dummy trenches 15, the dummy electrodes 58 are insulated from the semiconductor substrate 12 by the dummy insulating films 56. Each dummy electrode 58 has an upper surface covered with the interlayer insulating film 20. In upper parts of the dummy trenches 15, the dummy electrodes 58 are insulated from the front surface electrode 22 by the interlayer insulating films 20. However, the dummy electrodes 58 are connected to the front surface electrode 22 at a position not shown in the drawings. The dummy electrodes 58 are not connected to the gate electrodes 18. That is, the dummy electrodes 58 are not electrically connected with the gate electrodes 18 at any positions and are electrically separated from the gate electrodes 18.

As shown in FIGS. 1, 2, and 4, emitter regions 30, anode regions 32, barrier regions 34, pillar regions 35, a drift region 38, collector regions 40, and cathode regions 42 are provided in the semiconductor substrate 12.

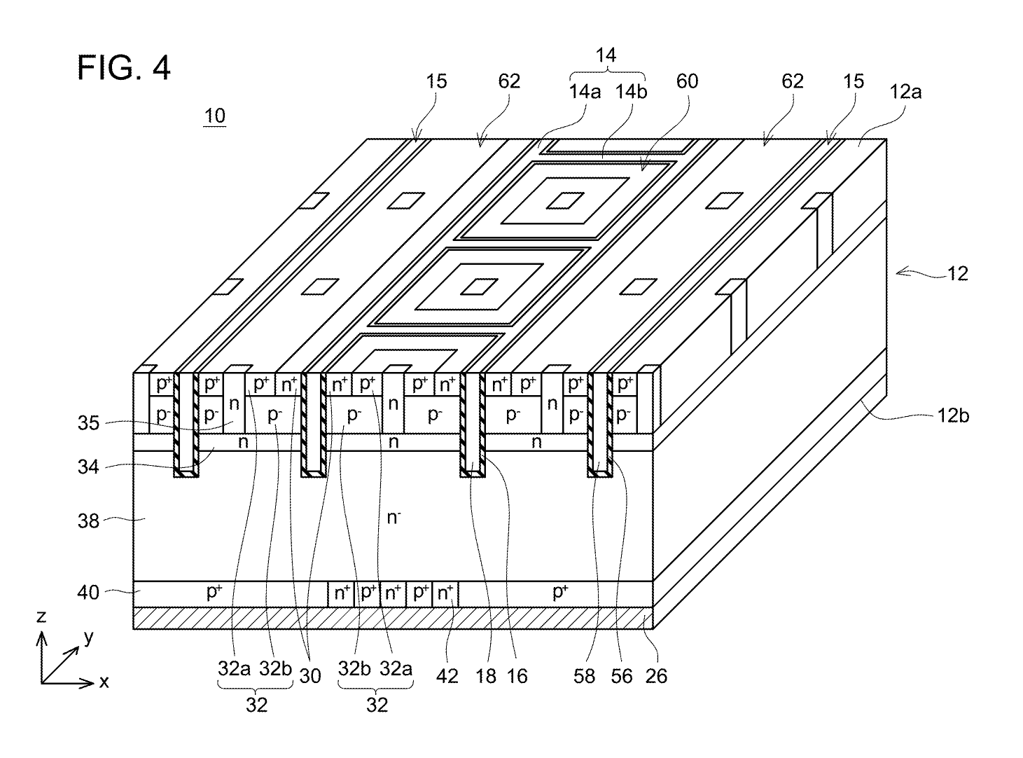

The emitter regions 30 are semiconductor regions of an n-type. As shown in FIG. 4, the emitter regions 30 are provided in the cell region 60 and in the external region 62. The emitter regions 30 are exposed on the front surface 12a of the semiconductor substrate 12. Each emitter region 30 forms ohmic contact with the front surface electrode 22. Each emitter region 30 is in contact with the gate insulating film 16. In each cell region 60, the emitter region 30 has an annular shape extending along the grid-structured gate trench 14. In each external region 62, the emitter region 30 extends in a straight line along the first gate trench 14a.

The anode regions 32 are semiconductor regions of a p-type. As shown in FIG. 4, the anode regions 32 are provided in the cell regions 60 and in the external regions 62. Each anode region 32 is an anode region of a diode and also functions as a body region of an IGBT (a region where a channel is to be formed). Each anode region 32 has a high-concentration anode region 32a and a low-concentration anode region 32b. The high-concentration anode region 32a is exposed on the front surface 12a of the semiconductor substrate 12 at a position adjacent to the emitter region 30. The high-concentration anode region 32a forms ohmic contact with the front surface electrode 22. In each cell region 60, the high-concentration anode region 32a has an annular shape extending along the emitter region 30. In each external region 62, the high-concentration anode region 32a is provided between the emitter region 30 and the dummy trench 15. A p-type impurity concentration in the low-concentration anode regions 32b is lower than that in the high-concentration anode regions 32a. The low-concentration anode regions 32b are provided under the emitter regions 30 and the high-concentration anode regions 32a. Each low-concentration anode region 32b is in contact with the emitter region 30 and the high-concentration anode region 32a. The low-concentration anode region 32b in each cell region 60 is in contact with the gate insulating film 16 at a position under the emitter region 30. The low-concentration anode region 32b in each external region 62 is in contact with the gate insulating film 16 at a position under the emitter region 30. The low-concentration anode region 32b in each external region 62 is further in contact with the dummy insulating film 56.

The barrier regions 34 are semiconductor regions of the n-type. As shown in FIG. 4, the barrier regions 34 are provided in the cell regions 60 and in the external regions 62. The barrier region 34 is provided under the anode region 32 and in contact with the anode region 32. The barrier region 34 extends like a plane in the directions x and y under the anode region 32. The barrier region 34 is separated from the emitter region 30 by the anode region 32. The barrier region 34 in the cell region 60 is in contact with the gate insulating film 16 at a position under the anode region 32. Each barrier region 34 in the external region 62 is in contact with the gate insulating film 16 at a position under the anode region 32. Each barrier region 34 in the external region 62 is further in contact with the dummy insulating film 56 at a position under the anode region 32.

The pillar regions 35 are semiconductor regions of the n-type. As shown in FIG. 4, the pillar regions 35 are provided in the cell regions 60 and in the external regions 62. Each pillar region 35 is lateral to the anode region 32 and is in contact with the anode region 32. Each pillar region 35 extends from the front surface 12a of the semiconductor substrate 12 to the barrier region 34 in the direction z (thickness direction of the semiconductor substrate 12). Each pillar region 35 has an upper end portion exposed on the front surface 12a of the semiconductor substrate 12 while forming Schottky contact with the front surface electrode 22. Each pillar region 35 has a lower end portion connected to the barrier region 34. Each pillar region 35 is separated from the emitter region 30 by the anode region 32. Each pillar region 35 is also separated from the gate insulating film 16. That is, the pillar region 35 in each cell region 60 is located in the center of the cell region 60 and is not in contact with the gate insulating film 16. The pillar region 35 in each external region 62 is located at a position surrounded by the anode region 32 and is not in contact with the gate insulating film 16. The pillar region 35 in each external region 62 is not connected to the dummy insulating film 56 either.

The drift region 38 is a semiconductor region of the n-type. An n-type impurity concentration in the drift region 38 is lower than that in the barrier regions 34. As shown in FIG. 4, the drift region 38 extends across positions under a plurality of cell regions 60 and positions under a plurality of external regions 62. The drift region 38 is in contact with the barrier regions 34. The drift region 38 is in contact with the gate insulating films 16 and the dummy insulating films 56 at positions under the barrier regions 34. The drift region 38 is separated from the anode regions 32 by the barrier regions 34.

The collector regions 40 are semiconductor regions of the p-type. As shown in FIG. 4, the collector regions 40 are provided under the drift region 38 and in contact with the drift region 38. The collector regions 40 are exposed on the rear surface 12b of the semiconductor substrate 12. Each collector region 40 forms ohmic contact with the rear surface electrode 26. The collector regions 40 are provided in lower parts of the external regions 62 and in lower part of the cell regions 60.

The cathode regions 42 are semiconductor regions of the n-type. The cathode regions 42 have an n-type impurity concentration higher than those in the drift region 38, the barrier regions 34, and the pillar regions 35. As shown in FIG. 4, the cathode regions 42 are provided under the drift region 38 and in contact with the drift region 38. The cathode regions 42 are exposed on the rear surface 12b of the semiconductor substrate 12 at positions adjacent to the collector regions 40. Each cathode region 42 forms ohmic contact with the rear surface electrode 26. A plurality of cathode regions 42 are provided in a lower part of the cell region 60.

In each cell region 60, the emitter region 30, the anode region 32 (i.e., body region), and the barrier region 34 configure a switching structure. The switching structure in each cell region 60 configures an IGBT connected between the front surface electrode 22 and the rear surface electrode 26 together with the drift region 38, the collector region 40, the gate electrode 18, the gate insulating film 16 and others. In each external region 62, the emitter region 30, the anode region 32 (i.e., body region), and the barrier region 34 also configure a switching structure. The switching structure in each external region 62 configures an IGBT connected between the front surface electrode 22 and the rear surface electrode 26 together with the drift region 38, the collector region 40, the gate electrode 18, the gate insulating film 16 and others. For operation of the IGBT, the front surface electrode 22 and the rear surface electrode 26 function as an emitter electrode and a collector electrode of the IGBT respectively.

The semiconductor substrate 12 is provided with pn diodes connected between the front surface electrode 22 and the rear surface electrode 26. Each of these pn diodes is formed of the anode region 32 in the cell region 60, the barrier region 34 in the cell region 60, the drift region 38, and the cathode region 42. The semiconductor substrate 12 is further provided with pn diodes connected between the front surface electrode 22 and the rear surface electrode 26. Each of these pn diodes is formed of the anode region 32 in the external region 62, the barrier region 34 in the external region 62, the drift region 38, and the cathode region 42. For operation of the pn diodes, the front surface electrode 22 and the rear surface electrode 26 function as an anode electrode and a cathode electrode of each pn diode respectively.

As described above, each of the pillar regions 35 forms a Schottky contact with the front surface electrode 22. The semiconductor substrate 12 is provided with Schottky barrier diodes (hereinafter called SBDs) connected between the front surface electrode 22 and the rear surface electrode 26. Each of these SBDs is formed of the pillar region 35 in the cell region 60, the barrier region 34 in the cell region 60, the drift region 38, and the cathode region 42. The semiconductor substrate 12 is further provided with SBDs connected between the front surface electrode 22 and the rear surface electrode 26. Each of these SBDs is formed of the pillar region 35 in the external region 62, the barrier region 34 in the external region 62, the drift region 38, and the cathode region 42. For operation of the SBDs, the front surface electrode 22 and the rear surface electrode 26 function as an anode and a cathode of each SBD respectively. That is, the pn diodes and the SBDs are connected in parallel between the front surface electrode 22 and the rear surface electrode 26.

The following will describe the operation of the IGBT. When turning on the IGBT, a potential higher than the potential of the front surface electrode 22 is applied to the rear surface electrode 26. In response to application of a threshold potential or a higher potential to the gate electrodes 18, a channel is formed in each anode region 32 near the gate insulating films 16. This causes electrons to flow from the front surface electrode 22 to the rear surface electrode 26 through the emitter regions 30, the channel in the anode regions 32, the barrier regions 34, the drift region 38, and the collector regions 40. Further, holes are caused to flow from the rear surface electrode 26 to the front surface electrode 22 through the collector regions 40, the drift region 38, the barrier regions 34, and the anode regions 32. That is, the IGBT is turned on to cause a current to flow from the rear surface electrode 26 to the front surface electrode 22. By reducing the potential of the gate electrodes 18 to be lower than the threshold thereafter, the channels disappear to stop the current flow. That is, the IGBT is turned off.

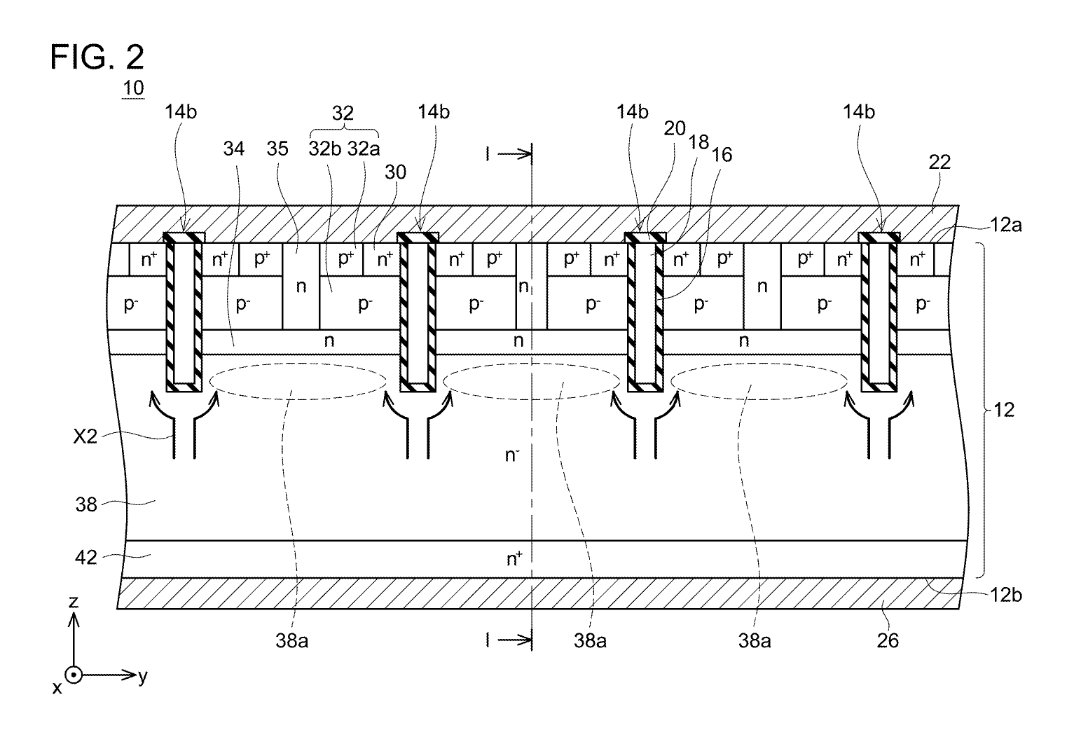

As shown by arrows X1 in FIG. 1, holes flowing in the drift region 38 while the IGBT is ON travel in both sides of each first gate trench 14a and also in both sides of each dummy trench 15. This makes the holes concentrate in the drift region 38 in lower parts of the cell regions 60 (regions 38a indicated by a dashed line of FIG. 1) and in the drift region 38 in lower parts of the external regions 62 (regions 38b indicated by a dashed line of FIG. 1). This reduces an electrical resistance in the regions 38a and 38b. In the description below, reduction in the resistance of the drift region 38 caused by concentration of holes flowing so as to bypass trenches is called carrier storage effect. Achieving the carrier storage effect in the regions 38a and 38b allows electrons to pass through the regions 38a and 38b with low loss. As shown by arrows X2 of FIG. 2, holes flow in the drift region 38 while bypassing the second gate trenches 14b. In the regions 38a in the lower parts of the cell regions 60, the carrier storage effect is further achieved by the second gate trenches 14b. That is, in the regions 38a in the lower parts of the cell regions 60, holes concentrate in both the direction x as shown by the arrows X1 of FIG. 1 and the direction y as shown by the arrows X2 of FIG. 2. This considerably reduces the electrical resistance of the regions 38a in the lower parts of the cell regions 60. In this way, the carrier storage effect becomes more potent in the regions 38a in the lower parts of the cell regions 60 surrounded by the first gate trenches 14a and the second gate trenches 14b. As a result, the ON voltage of the IGBT is low.

The operation of the pn diodes and the operation of the SBDs will be described next. When turning on the pn diodes and the SBDs, a voltage (forward voltage) to place the front surface electrode 22 at a high potential is applied between the front surface electrode 22 and the rear surface electrode 26. The following description will proceed on the assumption that the potential of the front surface electrode 22 is increased gradually from a potential substantially equal to that of the rear surface electrode 26. Increasing the potential of the front surface electrode 22 causes a current flow in Schottky contact parts at interfaces between the pillar regions 35 and the front surface electrode 22. That is, the SBDs are turned on. This causes electrons to flow from the rear surface electrode 26 to the front surface electrode 22 through the drift region 38, the barrier regions 34, and the pillar regions 35. Turning on the SBDs makes the potential of the barrier regions 34 approximate to the potential of the front surface electrode 22. This makes it difficult to generate a potential difference at the pn junctions at boundaries between the anode regions 32 and the barrier regions 34. Thus, even raising the potential of the front surface electrode 22 thereafter does not turn on the pn diodes for a while. Increasing the potential of the front surface electrode 22 further increases a current flowing in the SBDs. Increasing the current flowing in the SBDs generates a larger potential difference between the front surface electrode 22 and the barrier regions 34, thereby increasing the potential difference generated at the pn junctions at the boundaries between the anode regions 32 and the barrier regions 34. Thus, raising the potential of the front surface electrode 22 to a certain potential or to a higher potential turns on the pn diodes. That is, holes flow from the front surface electrode 22 to the rear surface electrode 26 through the anode regions 32, the barrier regions 34, the drift region 38, and the cathode regions 42. Further, electrons flow from the rear surface electrode 26 to the front surface electrode 22 through the cathode regions 42, the drift region 38, the barrier regions 34, and the anode regions 32. In this way, in the semiconductor device 10, the SBDs are turned on before the potential of the front surface electrode 22 rises, thereby delaying timing of turning-on of the pn diodes. This suppresses flow of holes from the anode regions 32 into the drift region 38.

Applying a reverse voltage (voltage to place the front surface electrode 22 at a low potential) between the front surface electrode 22 and the rear surface electrode 26 after turning-on of the pn diodes causes the pn diodes to perform a reverse recovery operation. That is, holes are present in the drift region 38 when the pn diodes are on. In response to application of the reverse voltage, the holes in the drift region 38 are discharged through the anode regions 32 to the front surface electrode 22. This flow of the holes instantaneously generates a reverse current in the pn diodes. However, in the semiconductor device 10, the SBDs suppress the flow of the holes from the anode regions 32 into the drift region 38 as described above when the pn diodes are turned on. Thus, not many holes are present in the drift region 38 during the reverse recovery operation of the pn diodes. This makes the reverse current that generates during the reverse recovery operation of the pn diodes small. In this way, the semiconductor device 10 suppresses the reverse current to be generated during the reverse recovery operation of the pn diodes.

The potential of the gate electrodes 18 changes when the SBDs operate. The semiconductor device 10 of this embodiment makes the change in the potential of the gate electrode 18 less influential on the SBDs and the pn diodes as described in detail below.

If the potential of the gate electrodes 18 is high, channels are formed in the anode regions 32. The presence of the channels in the anode regions 32 during operation of the SBDs makes the potential of the barrier regions 34 near the gate insulating films 16 approximate to the potential of the front surface electrode 22. This makes it difficult to generate a potential difference at the Schottky contact parts of the SBDs (contact parts between the pillar regions 35 and the front surface electrode 22). This phenomenon is not caused if the potential of the gate electrodes 18 is low and the channels are not formed. Thus, a forward voltage required for turning on the SBDs varies depending on the potential of the gate electrodes 18. The variation in the forward voltage of the SBDs then varies a forward voltage required for turning on the pn diodes. Such a phenomenon in the RC-IGBT where the characteristics of a diode varies depending on the potential of the gate electrodes 18 is called gate interference. If the pillar regions 35 are provided near the grid-structured gate trenches 14, the lower end portions of the pillar regions 35 becomes close to a lower end portions of the channels. This makes the gate interference more influential. That is, if a clearance W4 (see FIG. 3) between the pillar region 35 and the grid-structured gate trench 14 is narrow, the characteristics of the SBDs and those of the pn diodes are made unstable by the gate interference.

In contrast, in the semiconductor device 10 of this embodiment, the clearance W4 is sufficiently large for the following reason. As described above, in the semiconductor device 10, the low on voltage of the IGBT is achieved by the grid-structured gate trench 14. The on voltage can be reduced effectively by the grid-structured gate trench 14. This eliminates the need for forming the gate trenches densely between two dummy trenches 15. This achieves a large clearance between two first gate trenches 14a and between two second gate trenches 14b. As a result, the clearance W4 between the pillar region 35 and the grid-structured gate trench 14 in each cell region 60 can be provided sufficiently large. This minimizes the influence of the gate interference in the cell regions 60. A clearance W5 between the pillar region 35 and the grid-structured gate trench 14 in each external region 62 is substantially equal to the clearance W4. This also minimizes the influence of the gate interference in the external regions 62. As a result, in the semiconductor device 10, the SBDs and the pn diodes are allowed to operate stably.

The potential of the gate electrodes 18 is further influential on the resistance value of the pillar regions 35. That is, change in the potential of the gate electrodes 18 changes an electric field generated from the gate electrodes 18, thereby changing a distribution of carries in the pillar regions 35. In this way, the resistance of the pillar regions 35 changes depending on the potential of the gate electrodes 18. The pillar regions 35 provided near the grid-structured gate trenches 14 make the electric field generated from the gate electrodes 18 more influential on the pillar regions 35. In the semiconductor device 10 of this embodiment, however, the clearances W4 and W5 each defined between the pillar region 35 and the grid-structured gate trench 14 are sufficiently large as described above. This minimizes change in the resistance of the pillar regions 35 to be caused by the influence of the electric field generated from the gate electrodes 18. This further contributes to stable operation of the SBDs and the pn diodes.

As described above, in the semiconductor device 10 of this embodiment, the pillar regions 35 are sufficiently spaced apart from the grid-structured gate trenches 14. This achieves the stable operation of the SBDs and the pn diodes.

As described above, in the semiconductor device 10 of this embodiment, the on voltage of the IGBT can sufficiently be reduced by the grid-structured gate trenches 14. Thus, a large number of gate trenches are not required to be located between two dummy trenches 15. This can narrow a clearance W1 (see FIG. 3) between the two dummy trenches 15.

In the semiconductor device 10 of this embodiment, each pillar region 35 in the external regions 62 is located near the dummy trenches 15. That is, as shown in FIG. 3, a clearance W6 between the pillar region 35 and the dummy trench 15 in the external region 62 is narrower than the clearance W5 between the pillar region 35 and the grid-structured gate trench 14 in the external region 62. Unlike that of the gate electrode 18, the potential of the dummy electrode 58 hardly changes. Thus, locating the pillar regions 35 in the external regions 62 near the dummy trenches 15 does not cause the gate interference or change the resistance of the pillar regions 35. Locating the dummy trench 15 near the pillar region 35 in the external region 62 in this way makes a clearance W3 between the first gate trench 14a and the dummy trench 15 narrower than a clearance W2 between the first gate trenches 14a adjacent to each other. Narrowing the clearance W3 in this way further narrows the clearance W1 between two dummy trenches 15.

The formation of the narrow clearance W1 between two dummy trenches 15 in the aforementioned way reduces a gate capacitance of the semiconductor device 10 of this embodiment. This enables high-speed switching of the IGBT.

As described above, in the semiconductor device 10 of this embodiment, the low on voltage of the IGBT is achieved by the grid-structured gate trench 14 without necessitating a large number of gate trenches between dummy trenches. Not many gate trenches are located between the dummy trenches, thereby narrowing the clearance W1 between the dummy trenches. This contributes to an increase in a switching speed of the IGBT. The grid-structured gate trench 14 achieves the low on voltage without narrowing each clearance between the gate trenches 14a and that between the gate trenches 14b. This makes it possible to form a large clearance between the pillar region 35 and the grid-structured gate trench 14, thereby achieving stable operation of the diode.

In the semiconductor device 10 of the aforementioned embodiment, the dummy electrodes 58 are connected to the front surface electrode 22. Alternatively, the dummy electrodes 58 may be electrically separated from the front surface electrode 22. That is, the potential of the dummy electrodes 58 may be a floating potential not fixed to the potential of the front surface electrode 22.

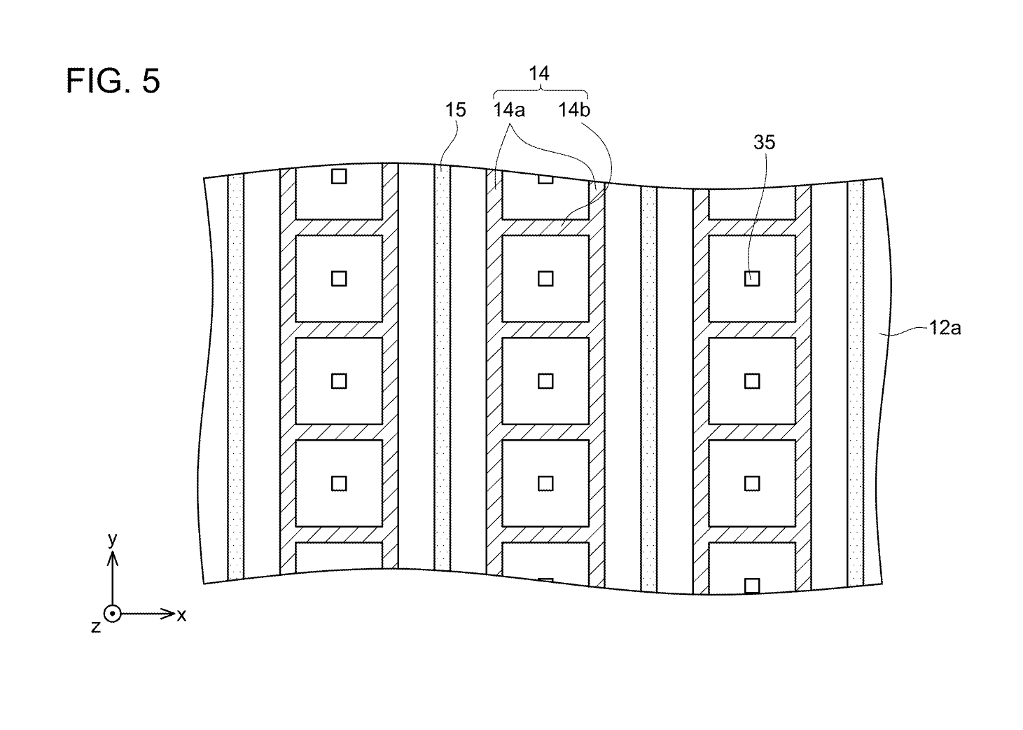

In the aforementioned embodiment, the pillar regions 35 are provided in the external regions 62. Alternatively, as shown in FIG. 5, the pillar regions 35 may be provided only in the cell regions 60 without being provided in the external regions 62.

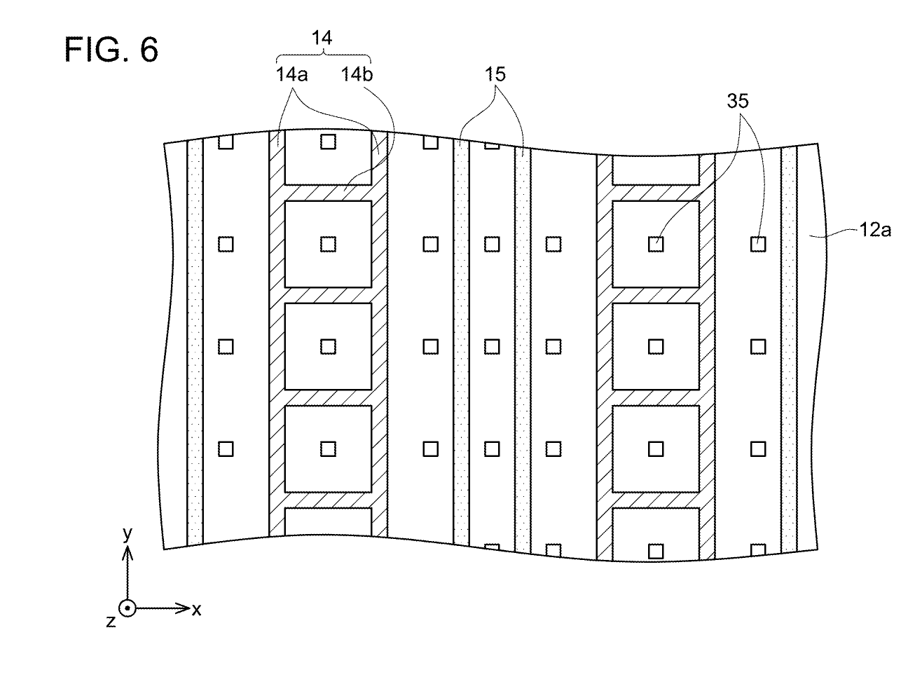

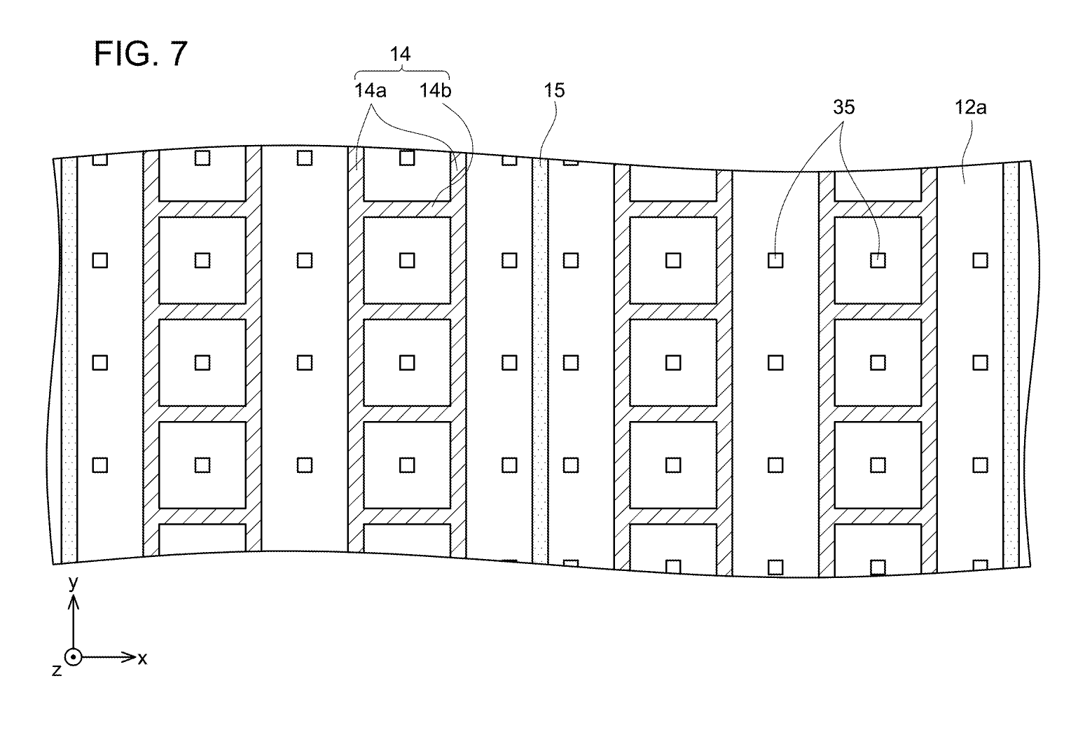

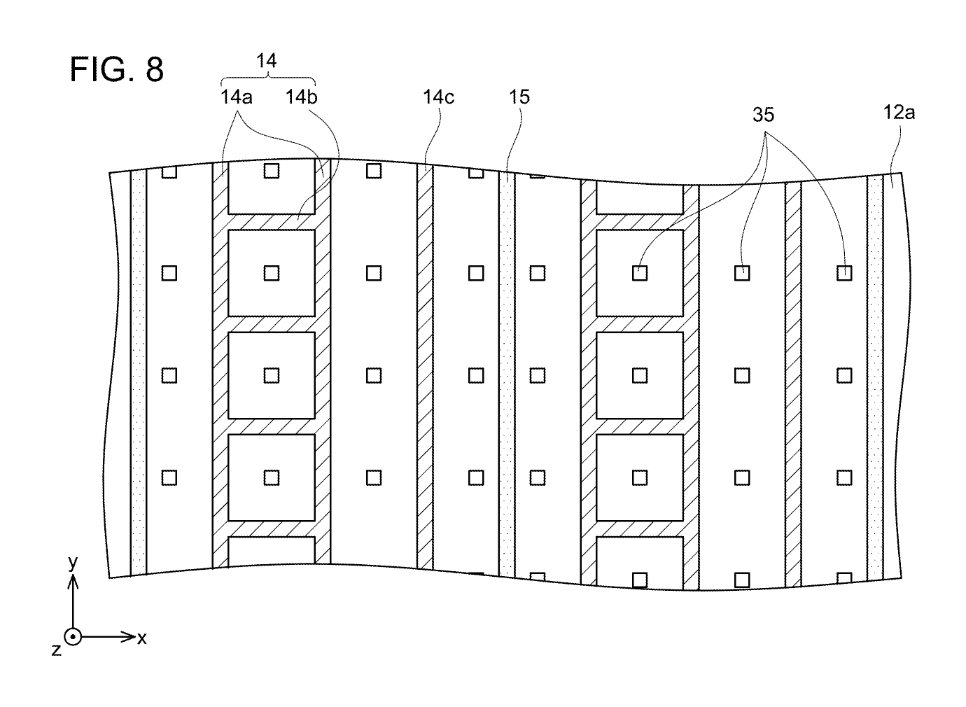

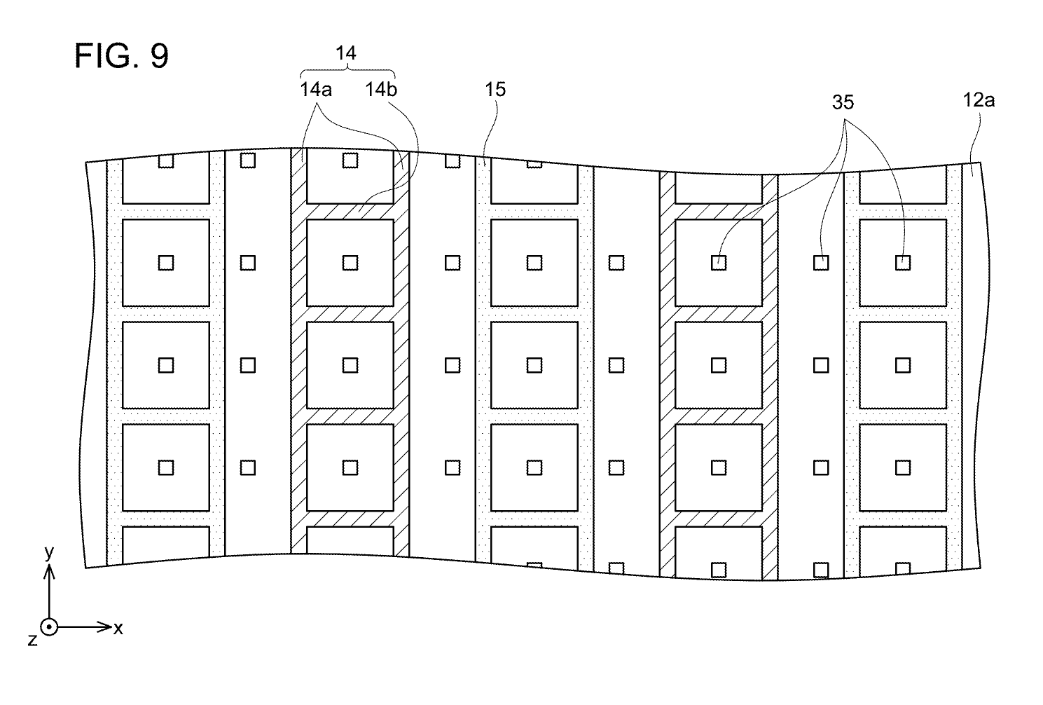

In the aforementioned embodiment, one grid-structured gate trench 14 and one dummy trench 15 are located alternately. Alternatively, as shown in FIG. 6, a plurality of dummy trenches 15 may be located between two grid-structured gate trenches 14. Still alternatively, as shown in FIG. 7, a plurality of grid-structured gate trenches 14 may be located between two dummy trenches 15. Further alternatively, as shown in FIG. 8, the grid-structured gate trench 14 and a gate trench 14c of a stripe shape may be located between two dummy trenches 15. Still alternatively, as shown in FIG. 9, the dummy trench 15 may have a grid structure.

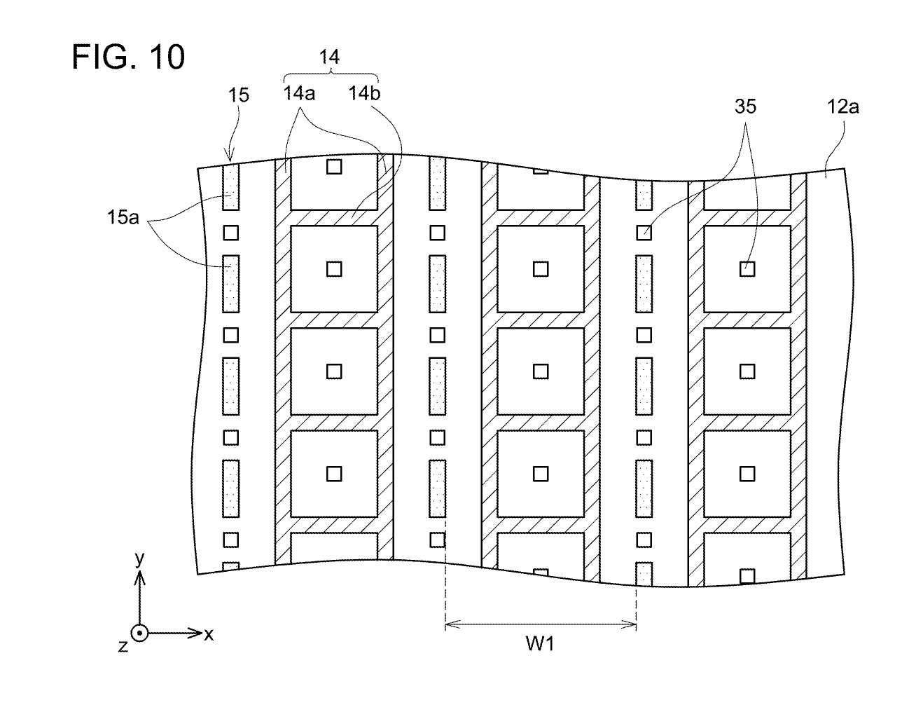

In the aforementioned embodiment, the dummy trench 15 extends like a stripe in the direction y. Alternatively, as shown in FIG. 10, dummy trench 15 may be provided discontinuously like a dashed line in the direction y. That is, the dummy trench 15 may have a large number of separation dummy trenches 15a arranged in the direction y and separated from one another. Even in this configuration, the dummy trench 15 still contributes to increasing a switching speed of the IGBT. In FIG. 10, the pillar region 35 is located between two separation dummy trenches 15a. The formation of the pillar region 35 in this way can narrow a clearance further between the dummy trench 15 and the first gate trench 14a. This can narrow the clearance W1 between the dummy trenches 15 further, thereby increasing the switching speed of the IGBT further.

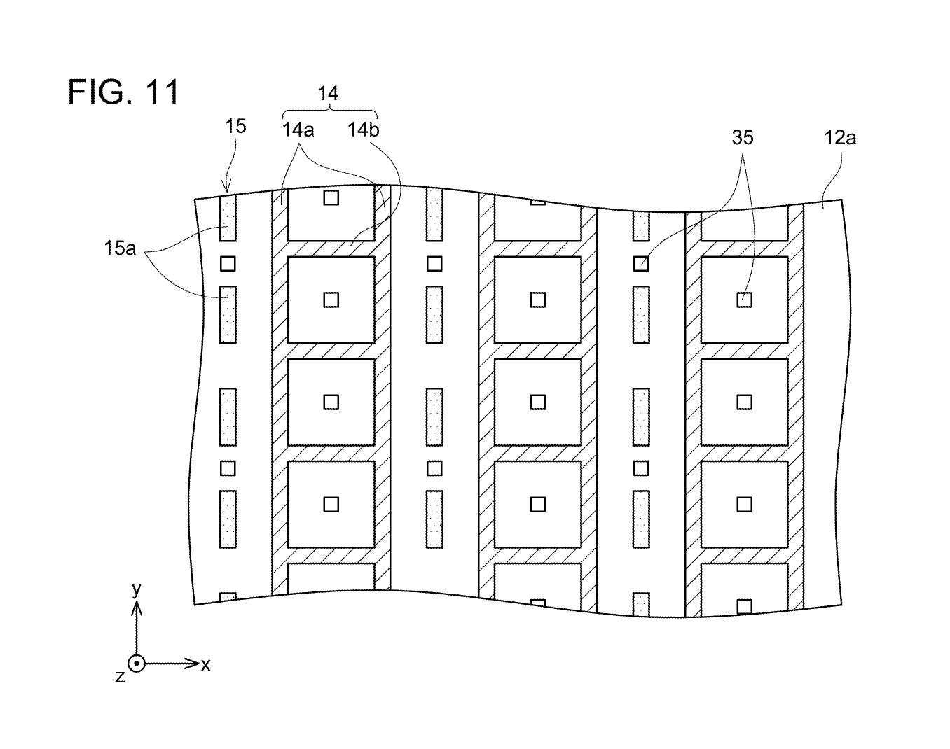

As shown in FIG. 11, the pillar regions 35 may be provided in some clearance areas defined between the separation dummy trenches 15a and may not be provided in the other clearance areas.

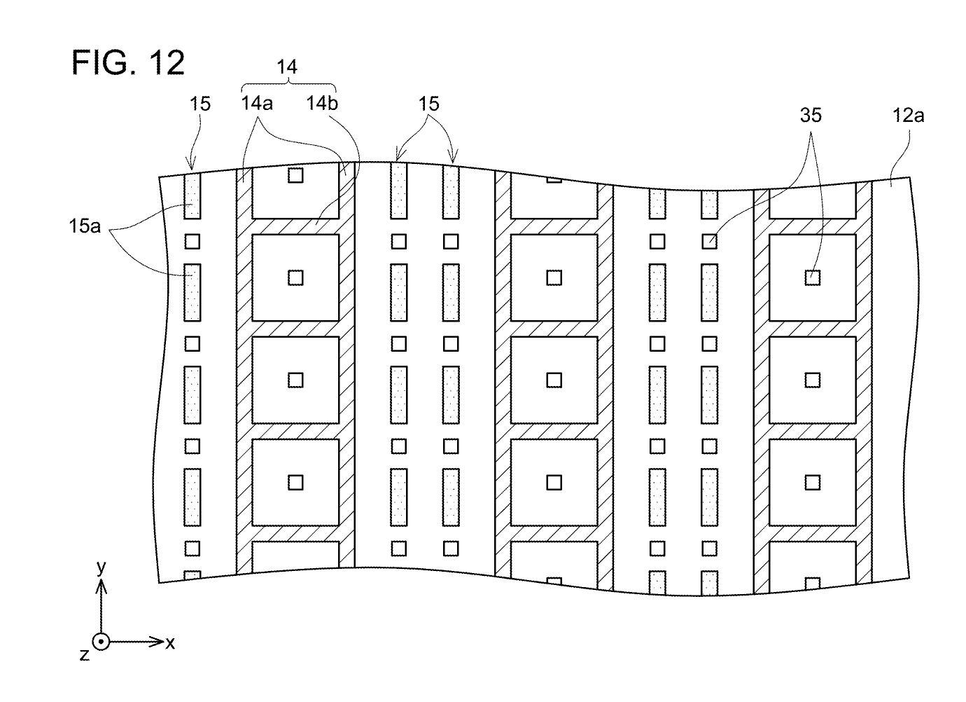

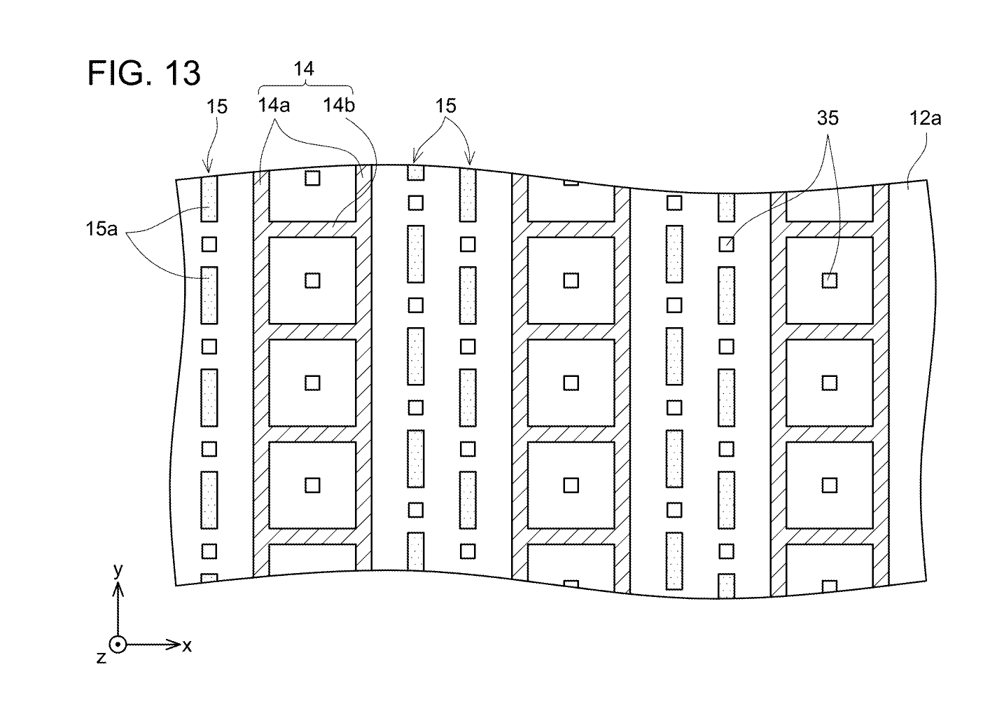

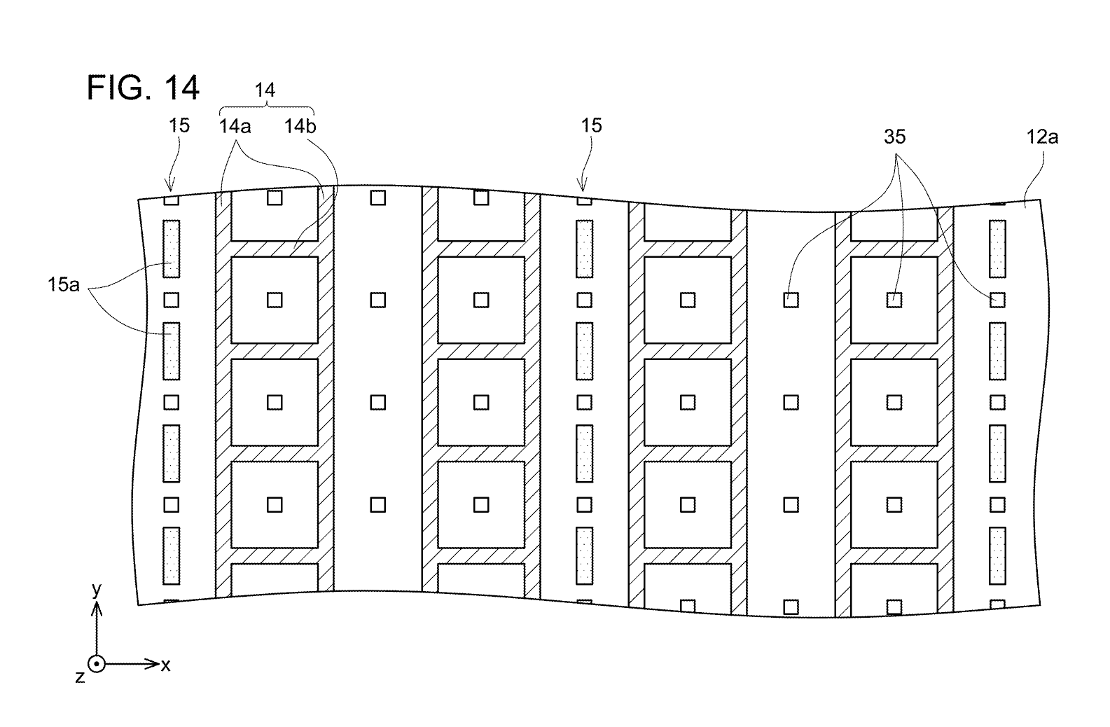

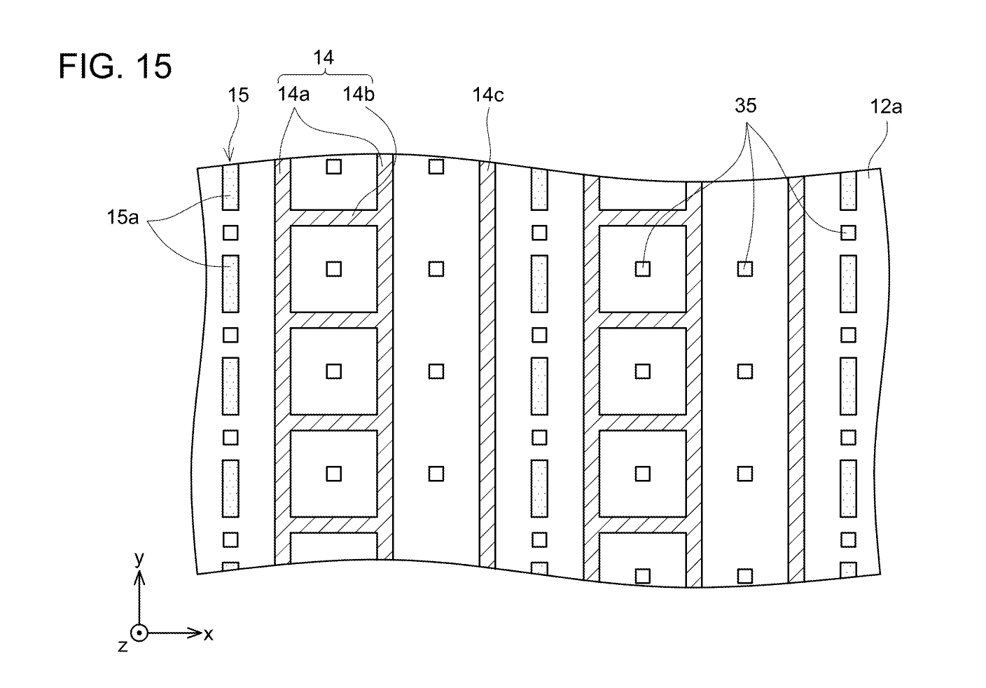

As shown in FIG. 12, a plurality of dummy trenches 15 like dashed lines may be located between two grid-structured gate trenches 14. As shown in FIG. 13, the respective separation dummy trenches 15a of the dummy trenches 15 like dashed lines adjacent to each other may be arranged in a staggered pattern. As shown in FIG. 14, a plurality of grid-structured gate trenches 14 may be located between two dummy trenches 15 like dashed lines. As shown in FIG. 15, the grid-structured gate trench 14 and the gate trench 14c of a stripe shape may be located between two dummy trenches 15 like dashed lines.

In the aforementioned embodiment or the aforementioned modifications of the embodiment, the pillar regions 35 may be in contact with the dummy trenches 15 (that is, the dummy insulating film 56). Making the pillar regions 35 contact the dummy trenches 15 still avoids a problem such as gate interference, so that the SBDs and the pn diodes are allowed to operate stably. In some cases, making the pillar regions 35 contact the dummy trenches 15 may enable the clearance W1 between the dummy trenches 15 to be further narrowed.

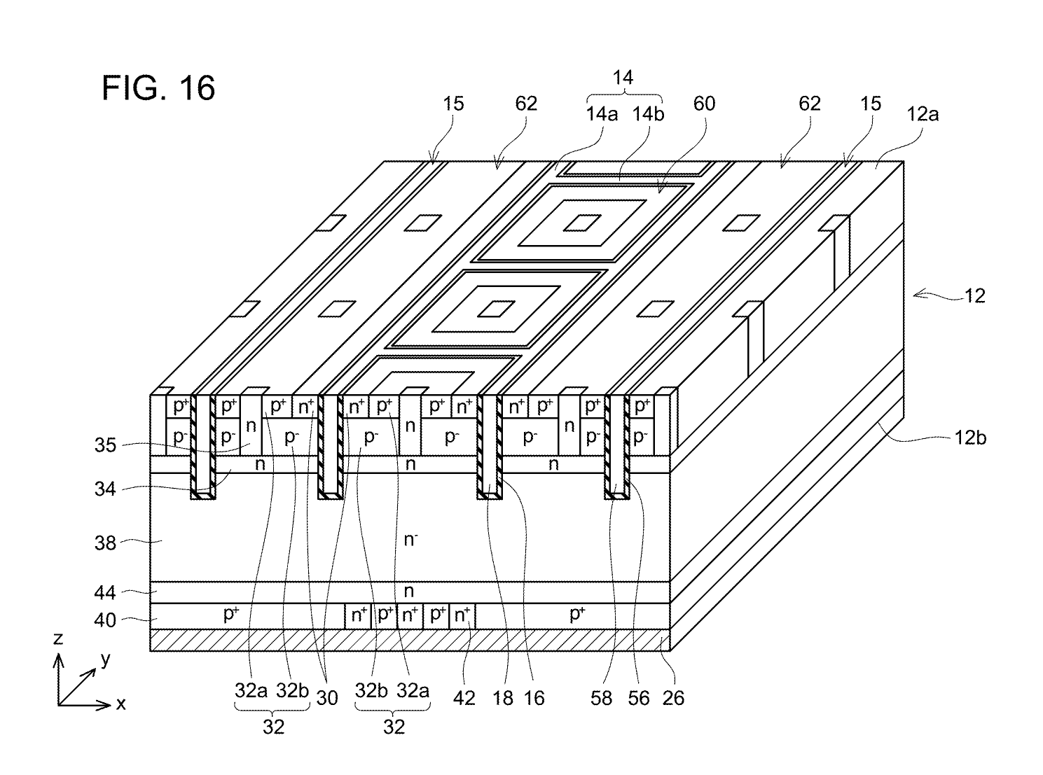

In the semiconductor device 10 of the embodiment, the collector regions 40 and the cathode regions 42 are in contact with the drift region 38. Alternatively, as shown in FIG. 16, a buffer region 44 may be provided under the drift region 38. The buffer region 44 is an n-type region having an n-type impurity concentration higher than that in the drift region 38 and lower than that in the cathode region 42. The collector region 40 and the cathode region 42 are provided under the buffer region 44. The collector region 40 and the cathode region 42 are separated from the drift region 38 by the buffer region 44.

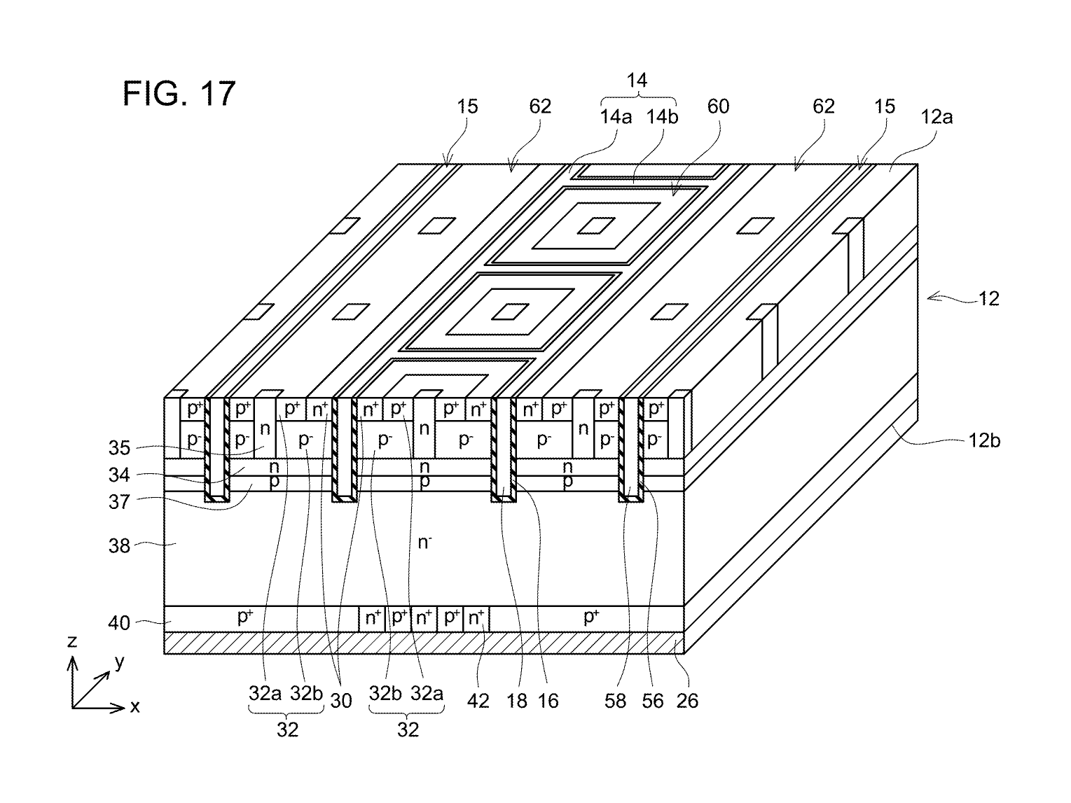

In the semiconductor device 10 of the embodiment, the barrier region 34 is in contact with the drift region 38. Alternatively, as shown in FIG. 17, intermediate regions 37 of the p-type may be provided between the barrier regions 34 and the drift region 38. The intermediate regions 37 are provided in the cell regions 60 and in the external regions 62. Each of the intermediate regions 37 is in contact with the gate insulating film 16 and the dummy insulating film 56 at positions under the barrier region 34. Each barrier region 34 is separated from the drift region 38 by the corresponding intermediate region 37. When the IGBT is turned on, channels are provided in the intermediate regions 37 as well as in the anode regions 32. The intermediate regions 37 allow more holes to be stored in the drift region 38 during operation of the IGBT. As a result, the on voltage of the IGBT can be reduced. A p-type impurity concentration is not so high in the intermediate region 37. Thus, when the SBD and the pn diodes are turned on, a current flows over the intermediate regions 37. Thus, even this configuration allows the semiconductor device 10 to operate as the RC-IGBT.

In the semiconductor device 10 of the embodiment, the pillar regions 35 form Schottky contact with the front surface electrode 22. Alternatively, the pillar regions 35 may form ohmic contact with the front surface electrode 22. In this configuration, current paths formed of the pillar regions 35, the barrier region 34, the drift region 38, and the cathode regions 42 function not for the SBDs but as resistors connected between the front surface electrode 22 and the rear surface electrode 26. In this case, the current flows in the current paths functioning as the resistors when the potential of the front surface electrode 22 rises. Then, the pn diodes are turned on. As a result, timing of turning-on of the pn diodes can be delayed. That is, flow of holes into the drift region 38 can be suppressed. Thus, even this configuration can similarly suppress the reverse current to be generated during the reverse recovery operation of the diode.

A configuration of a semiconductor device disclosed in this specification will be described below. In a semiconductor device disclosed herein as an example, the semiconductor substrate may further comprise a second anode region, a second barrier region, and a second pillar region. The second anode region may be of the p-type, located in at least one of the external regions which are regions between the first gate trench and the dummy gate trench adjacent to each other, and in contact with the gate insulating film and the front surface electrode. The second barrier region may be of the n-type, located in the at least one external region, in contact with the gate insulating film at a position on the rear surface side of the second anode region, and in contact with the dummy insulating film. The second pillar region may be of the n-type, configured to extend along the thickness direction, in contact with the front surface electrode, connected to the second barrier region, and separated from the gate insulating film. The drift region may be located across a position on the rear surface side of the first barrier region and a position on the rear surface side of the second barrier region. The drift region may be separated from the second anode region by the second barrier region. The drift region may have the n-type impurity concentration lower than that in the second barrier region.

In this configuration, the second anode region and the second barrier region in the external region configure a pn diode. The second pillar region and the front surface electrode in the external region configure an SBD. This allows the diode in the external regions to operate in the same way as in the cell regions.

In a semiconductor device disclosed herein as an example, the second pillar region may be located in the at least one external region.

In a semiconductor device disclosed herein as another example, each of the dummy trenches may comprise a plurality of separation dummy trenches arranged along the first gate trenches and separated from one another. The second pillar region may be located between at least one pair of separation dummy trenches adjacent to each other.

In a semiconductor device disclosed herein as an example, a clearance between the second pillar region and the first gate trench may be larger than a clearance between the second pillar region and the dummy trench.

If the second pillar region is located away from the gate trench in this manner, the diode can operate stably in the external region. Also, if the second pillar region is located near the dummy trench in this manner, a clearance between dummy trenches on the opposite sides of the grid-structured gate trench can be narrowed.

In a semiconductor device disclosed herein as an example, a clearance between the first gate trenches adjacent to each other may be larger than both of clearances between the dummy trench and the first gate trench adjacent to each other on both sides of the grid-structured gate trench.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A semiconductor device, comprising:
a semiconductor substrate;
a front surface electrode located on a front surface of the semiconductor substrate; and
a rear surface electrode located on a rear surface of the semiconductor substrate,
wherein
a plurality of dummy trenches and a grid-structured gate trench are provided in the front surface, the grid-structured gate trench being located between the dummy trenches,
the grid-structured gate trench comprises:
a plurality of first gate trenches extending along the dummy trenches on the front surface; and
a plurality of second gate trenches connecting the first gate trenches to each other,
a gate insulating film and a gate electrode are located in the grid-structured gate trench, the gate electrode being insulated from the semiconductor substrate by the gate insulating film,
a dummy insulating film and a dummy electrode are located in the respective dummy trenches, each dummy electrode being electrically separated from the gate electrode and insulated from the semiconductor substrate by the dummy insulating film, and
the semiconductor substrate comprises:
an emitter region being of an n-type, located in a cell region which is a region surrounded by the first gate trenches and the second gate trenches, and being in contact with the gate insulating film and the front surface electrode;
a first anode region being of a p-type, located in the cell region, being in contact with the gate insulating film at a position on a rear surface side of the emitter region, and being in contact with the front surface electrode;
a first barrier region being of the n-type, located in the cell region, and being in contact with the gate insulating film at a position on the rear surface side of the first anode region;
a first pillar region being of the n-type, located in the cell region, extending along a thickness direction of the semiconductor substrate, being in contact with the front surface electrode, connected to the first barrier region, and separated from the gate insulating film;
a drift region being of the n-type, located on the rear surface side of the first barrier region, separated from the first anode region by the first barrier region, and having an n-type impurity concentration lower than that in the first barrier region;
a collector region being of the p-type and in contact with the rear surface electrode; and
a cathode region being of the n-type, being in contact with the rear surface electrode, and having an n-type impurity concentration higher than that in the drift region.

2. The semiconductor device of claim 1, wherein
the semiconductor substrate further comprises:
a second anode region being of the p-type, located in at least one of external regions which are regions between the first gate trench and the dummy gate trench adjacent to each other, and being in contact with the gate insulating film and the front surface electrode;
a second barrier region being of the n-type, located in the at least one external region, being in contact with the gate insulating film at a position on the rear surface side of the second anode region, and being in contact with the dummy insulating film; and
a second pillar region being of the n-type, extending along the thickness direction, being in contact with the front surface electrode, connected to the second barrier region, and separated from the gate insulating film, and
the drift region is located across a position on the rear surface side of the first barrier region and a position on the rear surface side of the second barrier region, separated from the second anode region by the second barrier region, and having the n-type impurity concentration lower than that in the second barrier region.

3. The semiconductor device of claim 2, wherein the second pillar region is located in the at least one external region.

4. The semiconductor device of claim 2, wherein each of the dummy trenches comprises a plurality of separation dummy trenches arranged along the first gate trenches and separated from one another, and
the second pillar region is located between at least one pair of separation dummy trenches adjacent to each other.

5. The semiconductor device of claim 2, wherein a clearance between the second pillar region and the first gate trench is larger than a clearance between the second pillar region and the dummy trench.

6. The semiconductor device of claim 1, wherein a clearance between the first gate trenches adjacent to each other is larger than both of clearances between the dummy trench and the first gate trench adjacent to each other on both sides of the grid-structured gate trench.
